(19) United States
(12) Patent Application Publication
(10) Pub. No.: US 2003/0129846 A1
(43) Pub. Date: Jul. 10, 2003

(54) Method for achieving a uniform material removal rate in a CMP process

(75) Inventors: Chi-Wen Liu, Hsinchu (TW); Ying-Lang Wang, Tai-chung (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/043,860

(22) Filed: Jan. 9, 2002

(51) Int. Cl. H01L 21/311

(52) U.S. Cl. 438/698

(57) ABSTRACT

A method for pre-etching a semiconductor wafer prior to a chemical mechanical polishing (CMP) process to achieve a uniform polishing rate including providing a wafer process surface having a layer of an oxide of a metal overlying said metal to be chemically mechanically polished; removing the layer of an oxide of the metal according to an etching process; cleaning the semiconductor wafer to include the wafer process surface according to a wet cleaning process; and, chemically mechanically polishing the wafer process surface according to a CMP process including applying at least an abrasive slurry to the wafer process surface.

### FIELD OF THE INVENTION

This invention generally relates to chemical mechanical polishing and more particularly to a method for achieving a more uniform material removal rate in a chemical mechanical polishing (CMP) process.

### BACKGROUND OF THE INVENTION

In semiconductor fabrication, various layers of insulating material, semiconducting material and conducting material are formed to produce a multilayer semiconductor device. The layers are patterned to create features that taken together, form elements such as transistors, capacitors, and resistors. These elements are then interconnected to achieve a desired electrical function, thereby producing an integrated circuit (IC) device. The formation and patterning of the various device layers are achieved using conventional fabrication techniques, such as oxidation, implantation, deposition, epitaxial growth of silicon, lithography, etching, and planarization.

Planarization, for example, is an increasingly important in semiconductor manufacturing technology. As device sizes decrease, the importance of achieving high resolution features through photolithographic processes correspondingly increases thereby placing more severe restraints on the degree of planarity of a semiconductor wafer processing surface. Excessive degrees of process surface nonplanarity will affect the quality of several semiconductor process including, for example, in a photolithographic process, the positioning the image plane of the process surface within an increasingly limited depth of focus window to achieve high resolution semiconductor feature patterns.

One planarization process is chemical mechanical polishing (CMP). CMP is increasingly being used for planarizing dielectrics and other layers, including applications with and smaller semiconductor fabrication processes. CMP planarization is typically used several different times in the manufacture of a multi-layer semiconductor device. For example, CMP is used as one of the processes in preparing a layered device structure in a multi-layer device for subsequent processing. CMP may be used at a stage for removing excess metal after filling conductive metal interconnects such as vias and trench lines which act to electrically interconnect the several layers and areas that make up a multi-layer semiconductor device.

In the formation of conductive interconnections, tungsten is selectively used for forming conductive areas including contacts and vias together with aluminum metal interconnection technology and the increasingly widely used copper interconnection technology. Tungsten is selectively used in certain of the metal interconnections in a multi-layer semiconductor device since it is in many cases more reliable compared to aluminum and copper.

In a typical process for forming conductive interconnections in a multi-layer semiconductor device, for example, a damascene process is used to form vias and trench lines for interconnecting different layers and areas of the multilayer device. Although there are several processes for forming a damascene structure, the process generally involves patterning and etching a semiconductor feature, for example a via opening within an insulating dielectric layer to make contact with a conductive area within an underlying layer of the multilayer device. The via opening (plug) may then be filled with for example, tungsten (W) to form a via (plug) followed by a CMP step to remove excess metal deposited on the insulating dielectric layer surface and to planarized the surface for a subsequent processing step. A second insulating dielectric layer is then deposited followed by patterning and etching the second insulating dielectric layer to form a trench opening situate over the vias. The trench opening is then filled with a metal, for example, copper, aluminum, or tungsten to form trench lines (intra-layer metal interconnections). A second CMP step is then carried out similar to the first CMP step to remove excess metal and to planarize the process wafer surface in preparation for further processing.

CMP is widely accepted as the preferred process for many planarization processes including planarizing tungsten plugs. CMP is the method of choice particularly for smaller device fabrication technologies including dimensions of less than 0.25 micron. CMP generally includes placing a process surface of the wafer in contact against a flat polishing surface, and moving the wafer and the polishing surface relative to one another. The polishing action is typically aided by a slurry which includes for example, small abrasive particles such as colloidal silica (SiO₂) or alumina (Al₂O₃) that abrasively act to remove a portion of the process surface. Additionally, the slurry may additionally include chemicals that react with the process surface to assist in removing a portion of the surface material, the slurry typically being separately introduced between the wafer surface and the polishing pad. During the polishing or planarization process, the wafer is typically pressed against a rotating polishing pad. In addition, the wafer may also rotate and oscillate back and forth over the surface of the polishing pad to improve polishing effectiveness.

In a typical tungsten CMP process (WCMP), in order to avoid plastic deformation induced defects into the tungsten metal surface caused by abrasive slurry particles, and to aid in global planarization (extending over the process wafer surface) by equalizing reaction rates of material removal across the process wafer surface, a slurry including abrasive particles and an tungsten oxide forming chemical are used to achieve both tungsten oxide formation over the tungsten surfaces and a suitably selective planarization (surface material removal) rate over the entire process wafer surface.

For example, in a typical tungsten CMP process (WCMP), a polishing slurry including colloidal silica (SiO₂) or alumina (Al₂O₃) abrasive particles, hydrogen peroxide (H₂O₂) and various acids or bases may be used. The hydrogen peroxide (H₂O₂) is used to oxidize the tungsten surface, forming tungsten oxide while the tungsten oxide is subsequently removed by the abrasive polishing process of the abrasive particles thereby creating a fresh tungsten surface for continued surface reaction between the hydrogen peroxide (H₂O₂) and the tungsten surface. The tungsten oxide is formed on the tungsten surface by an in-situ chemical reaction induced over the tungsten surface. The in-situ generated tungsten oxide typically includes a hydroxide of tungsten (e.g., W(OH)ₓ) referred to herein as tungsten oxide as well as the more familiar form of tungsten oxide (e.g., WO₃), both forms hereinafter referred to as tungsten oxide.

For example, FIGS. 1A-1C are conceptual side view representations of a portion of a semiconductor wafer surface showing tungsten oxide formation and removal according to the prior art. In FIG. 1A is shown a layer of tungsten 14 overlying insulating dielectric layer 12, tungsten layer 14 showing an ideal representation of a newly formed tungsten surface 14A.

FIG. 1B shows the formation of tungsten oxide layer 16 over the tungsten surface 14A during a standard WCMP process whereby an oxidizing chemical such as hydrogen peroxide oxidizes the tungsten surface to form an in-situ generated film of tungsten oxide (e.g., W(OH)ₓ).

FIG. 1C shows the desirable consequence of the method according to the prior art where a low spot including the tungsten oxide film 16 is removed at a relatively slow rate while removing the tungsten oxide film 16 at a high spot e.g., 18, and leaving a portion of the tungsten oxide 16 film at a low spot, e.g., 20.

FIG. 1D shows a dense tungsten oxide (e.g., WO₃) film 22 formed on most tungsten surfaces by ambient oxidation processes (aging) of the tungsten surface. This tungsten oxide film typically includes the general formula WO₃, being more dense compared to the in-situ generated tungsten oxide film (e.g., W(OH)ₓ) produced during the slurry polishing process. As a result, the problem of uniformly removing an in-situ generated tungsten oxide film (e.g. W(OH)ₓ) is exacerbated by the presence of the denser tungsten oxide film formed by aging processes. The rate of surface material removal using an abrasive slurry of the prior art including an oxidizing chemical, for example, hydrogen peroxide, is much slower over a tungsten oxide surface compared to a tungsten surface.

During WCMP, ideal performance is achieved by a balance achieved between tungsten oxide formation and removal giving an overall rate of removal of surface material. If the rate of tungsten oxide (removal is too fast, abrasive particles will form scratches readily observed on the process wafer surface. Conversely, if the rate of tungsten oxide removal is too slow, polishing efficiency will be reduced, consuming large amounts of expensive slurry and leaving undesired areas of tungsten oxide on the process wafer surface.

One problem according to the prior art process is the difficulty in achieving the proper balance between tungsten oxide formation and tungsten oxide removal, thereby achieving a more uniform and efficient removal rate. For example, during the initial polishing period if a preformed tungsten oxide layer is present, being formed by ambient oxidation processes (aging), the material removal (polishing) rate is very slow causing expensive slurry to be inefficiently consumed in the removal of the preformed tungsten oxide overlayer.

Therefore, there is a need in the semiconductor art to develop a CMP method for planarizing dielectric layers including tungsten semiconductor features such that the CMP process is more efficient leading to a more uniform material removal rate with a lower usage of polishing slurry.

It is therefore an object of the invention to provide a CMP method for planarizing dielectric layers including tungsten semiconductor features such that the CMP process is more efficient leading to a more uniform material removal rate with a lower usage of polishing slurry while overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for pre-etching a semiconductor wafer prior to a chemical mechanical polishing (CMP) process to achieve a uniform polishing rate.

In a first embodiment according to the present invention, the method includes providing a wafer process surface having a layer of an oxide of a metal overlying said metal to be chemically mechanically polished; removing the layer of an oxide of the metal according to an etching process; cleaning the semiconductor wafer to include the wafer process surface according to a wet cleaning process; and chemically mechanically polishing the wafer process surface according to a CMP process including applying at least an abrasive slurry to the wafer process surface.

In another embodiment, the layer of an oxide of the metal is at least one of an oxide of copper, aluminum, and tungsten.

In another related embodiment, the step of removing the layer of an oxide of the metal further includes using a wet chemical etchant wherein the wafer process surface is subjected to at least one of dipping into the wet chemical etchant and spraying the wet chemical etchant onto the wafer process surface while simultaneously agitating the wafer process surface. Further, agitating the wafer process surface includes at least one of megasonic energy and brushing. Further, yet, the wet chemical etchant is an aqueous basic solution with a pH of greater than about 10. Yet further, the wet chemical etchant includes potassium hydroxide (KOH).

In another embodiment, the step of removing the layer of an oxide of the metal further includes plasma etching the layer of an oxide of the metal according to a reactive ion etch process. Further, the reactive ion etch process further includes igniting and maintaining a plasma including at least one of fluorocarbons and hydrofluorocarbons.

In another embodiment, the wet cleaning process includes using deionized water wherein the wafer process surface is subjected to at least one of dipping into the deionized water and spraying the deionized water onto the wafer process surface while simultaneously agitating the wafer process surface.

In other related embodiments, the step of chemically mechanically polishing further includes applying a polishing solution to the wafer process surface for forming an oxide layer in-situ over the metal. Further, the polishing solution includes at least hydrogen peroxide. Further yet, the method includes a wafer process surface cleaning step following the step of chemically mechanically polishing.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A to 1D are conceptual schematic representations of an exemplary semiconductor feature with an exemplary metal overlayer including an oxide overlayer showing a chemical mechanical polishing process according to the prior art.

FIG. 2 is a graphical representation of a material removal rate in a chemical mechanical polishing process before and after removal of an oxide overlayer according to the present invention.

FIG. 3 is a process flow diagram showing one embodiment of the method according to the present invention.

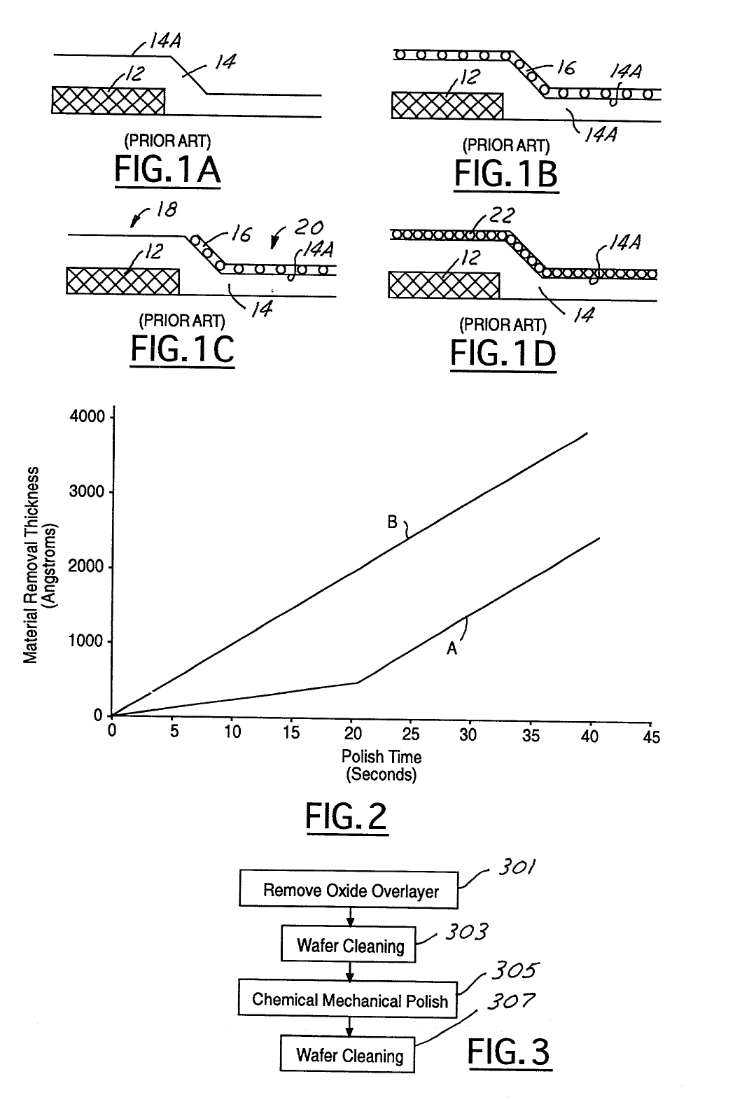

### DETAILED DESCRIPTION OF THE PREFERRED EMBODIMENTS

While the method according to the present invention is explained primarily with reference to an overlayer of tungsten oxide, it will be appreciated that the method of the present invention may be advantageously used prior to any CMP process where a metal oxide overlayer formed by ambient oxidation (aging) or otherwise is present and the metal oxide overlayer may be advantageously removed in order to optimize a surface material (e.g., metal) removal rate in a CMP process.

In the method according to the present invention, a metal oxide layer, for example tungsten oxide (e.g., WO₃) formed over a metal surface, for example tungsten, by ambient oxidation processes, is removed from the metal surface prior to performing a CMP planarization process.

FIG. 2 shows an representation of data showing the amount of surface material removed on the vertical axis with over a time interval on the horizontal axis for a process wafer undergoing CMP. Line A represents the amount of material removed over a time interval for a process surface with a tungsten oxide layer present, formed for example, by ex-situ oxidation (aging) processes.

Typically, the rate of polishing or surface material removal in tungsten CMP (WCMP) is initially very slow as the rate of oxide removal is slower than for the underlying metal (e.g., tungsten). As shown in FIG. 2, material removal versus time is depicted where the rate of material removal is represented by a change in removed thickness over time. It is seen that the initial removal rate (polishing rate) represented by line A is initially slow during the time period the tungsten oxide is removed being removed (less than about 20 seconds) For example, the slope (rate of surface material removal) can be seen to increase significantly after about 20 seconds during which the tungsten oxide overlayer is removed. Thereafter, the surface material removal rate is significantly faster and remains about constant.

In contrast, line B shows the surface material removal behavior if the tungsten oxide overlayer is first removed according to the present invention prior to performing the CMP process. Line B, it is seen, immediately displays a constant rate of material removal beginning at time zero and continuing for the duration of the CMP process. As a result, the polishing time is significantly reduced, thereby increasing a wafer throughput and saving the cost of slurry polishing solution.

In one embodiment of the present invention, the overlayer of tungsten oxide is removed according to a wet chemical etching process. For example, a basic etching solution with a pH greater than about 10 may be used. For example, an aqueous solution of potassium hydroxide (KOH) with a pH greater than about 10 is a suitable basic etching solution for forming a chemical etchant for removing the overlayer of tungsten oxide. It is believed that the tungsten oxide overlayer is removed by solvating ions according to the reaction:

WO₃+KOH(aq. Soln. pH.>10)?WO₄²⁻

According one embodiment of the present invention, a semiconductor process wafer may be directly dipped into the basic etchant solution. Following the direct dip process, the semiconductor process wafer may be subjected to a brush cleaning process to remove any loosened tungsten oxide layer particles remaining on the process wafer surface and to clean the process wafer.

For example, a DNS brush cleaner has suitable properties for brush cleaning the process wafer according to the present invention following the direct dip process to remove the tungsten oxide overlayer. For example, the Dai Nippon Screen Model No. SP-W813-AS (DNS brush cleaner) cleans the wafer using a combination of rinsing, megasonic rinsing, and brush cleaning.

In exemplary operation, the process wafers are loaded into a wet environment, usually de-ionized water, then transported through a series of cleaning chambers for the brush cleaning cycle. The brush cleaning cycle involves rotating the process wafer at high speed, for example, about 1500 rpm, while a jet of deionized water is sprayed on the process wafer and the process wafer surface is brushed with a foam brush to dislodge any loose debris.

During the brush cleaning cycle, the brush is first placed over the center of the wafer. The brush contacts the backside of the wafer, presses down on the wafer, and moves at a constant height and pressure to the periphery of the wafer in one stroke. The brush then retracts from the wafer and the whole cycle is repeated. Additional chambers brush the top side of the wafer. After the brushing cycles, the wafer is deposited in the spin/rinse/dry chamber and unloaded dry.

After the brush cleaning process according to the present invention, the process wafer is subjected to a CMP process. For example, a suitable CMP process for a tungsten surface includes a solids content of colloidal silica (SiO₂) of about 3 percent to about 7 percent, more preferably, 5 percent, the colloidal silica, for example, having an average diameter ranging from about 12 microns to about 50 microns. Preferably a basic CMP solution with a pH of greater than about 10 is used, including for example, KOH or NH3OH, and H₂O₂.

The CMP process is carried out as a conventional CMP process, for example, in operation, the wafer surface to be polished (target surface) is pressed against the polishing surface of the polishing pad. The down-force between the target surface and the polishing surface of the polishing pad is typically between 5 and 50 psi. The polishing slurry is deposited on the polishing pad, and the target surface and polishing pad are moved with respect to each other to impart relative motion therebetween.

It will be appreciated that the tungsten oxide may be chemically removed by means other than dipping. For example, the same wet etching solution used in the dipping process for removing the tungsten oxide overlayer, for example, a basic aqueous solution of potassium hydroxide (KOH) with a pH of greater than about 10, may be used, for example, in a DNS brushing and cleaning machine chamber in place of a rinsing solution. In this embodiment, different chambers may be equipped with different solutions for example wet etching and rinsing solutions, for alternatively chemically wet etching and cleaning the process wafer. Following the wet etching and cleaning process, the process wafer may proceed to the CMP step for polishing and to another cleaning step following the CMP step.

For example referring to FIG. 3, is a process flow diagram according to the present invention where the first step includes removal of oxide overlayer 301, for example tungsten oxide. Following the removal of the oxide overlayer, the process wafer is subjected to a wafer cleaning process 303, for example using a wet brush cleaning process. Following the wafer cleaning process, the process wafer is subjected to a CMP process 305, using a conventional CMP process to polish the non-oxide material underlying the oxidized material, for example, tungsten underlying tungsten oxide. Following the CMP process 305, the process wafer may optionally be subjected to another wet cleaning process 307, with for example a wet brush cleaning process similar to step 303.

In another embodiment according to the present invention, the step including removal of the oxide overlayer (step 401) may be accomplished by a reactive ion etching (RIE) process. For example, in this embodiment, the process wafer is subjected to a conventional RF generated plasma to remove the oxide layer from the process wafer surface. Suitable plasma chemistries include hydrofluorocarbons such as CF₄. Suitable plasma reactor operating conditions in for example a dual RF plasma reactor include hydrofluorocarbon and O₂ gas feed rates of, for example, CF₄ at 20 to 50 sccm and O₂ at 10 to 20 sccm with a total pressure of about 5 to about 20 mTorr while maintaining the first RF power source at about 200 to about 300 Watts and the second RF power source at about 100 to 150 Watts.

Following the RIE process to etchback the tungsten oxide overlayer, the process wafer may be subjected to steps 403, 405, and 407 as included following the wet etching process to remove the tungsten oxide overlayer.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for pre-etching a semiconductor wafer prior to a chemical mechanical polishing (CMP) process to achieve a uniform polishing rate comprising the steps of:
providing a wafer process surface having a layer of an oxide of a metal overlying said metal to be chemically mechanically polished;
removing the layer of an oxide of the metal according to an etching process;
cleaning the semiconductor wafer to include the wafer process surface according to a wet cleaning process; and
chemically mechanically polishing the wafer process surface according to a CMP process including applying at least an abrasive slurry to the wafer process surface.

2. The method of claim 1, wherein the layer of an oxide of the metal is at least one of an oxide of copper, aluminum, and tungsten.

3. The method of claim 1, wherein the step of removing the layer of an oxide of the metal further comprises using a wet chemical etchant wherein the wafer process surface is subjected to at least one of dipping into the wet chemical etchant and spraying the wet chemical etchant onto the wafer process surface while simultaneously agitating the wafer process surface.

4. The method of claim 3, wherein agitating the wafer process surface includes at least one of megasonic energy and brushing.

5. The method of claim 3, wherein the wet chemical etchant is an aqueous basic solution with a pH of greater than about 10.

6. The method of claim 5, wherein the wet chemical etchant includes potassium hydroxide (KOH).

7. The method of claim 1, wherein the step of removing the layer of an oxide of the metal further comprises plasma etching the layer of an oxide of the metal according to a reactive ion etch process.

8. The method of claim 7, wherein the reactive ion etch process further includes igniting and maintaining a plasma including at least one of fluorocarbons and hydrofluorocarbons.

9. The method of claim 1, wherein the wet cleaning process comprises using deionized water wherein the wafer process surface is subjected to at least one of dipping into the deionized water and spraying the deionized water onto the wafer process surface while simultaneously agitating the wafer process surface.

10. The method of claim 1, wherein the CMP process further includes applying a polishing solution to the wafer process surface for forming an oxide layer in-situ over the metal.

11. The method of claim 10, wherein the polishing solution includes at least hydrogen peroxide.

12. The method of claim 1, further including a wafer process surface cleaning step following the step of chemically mechanically polishing.

13. A method for pre-etching a semiconductor wafer prior to a chemical mechanical polishing (CMP) process to achieve a uniform polishing rate comprising the steps of:
providing a wafer process surface having a layer of an oxide of a metal overlying the metal to be chemically mechanically polished; and
removing the layer of an oxide of the metal according to an etching process.

14. The method of claim 13, wherein the layer of an oxide of the metal is at least one of an oxide of copper, aluminum, and tungsten.

15. The method of claim 13, wherein the step of removing the layer of an oxide of the metal further comprises using a wet chemical etchant wherein the wafer process surface is subjected to at least one of dipping into the wet chemical etchant and spraying the wet chemical etchant onto the wafer process surface while simultaneously agitating the wafer process surface.

16. The method of claim 15, wherein agitating the wafer process surface includes at least one of megasonic energy and brushing.

17. The method of claim 15, wherein the wet chemical etchant is an aqueous basic solution with a pH of greater than about 10.

18. The method of claim 17, wherein the wet chemical etchant includes potassium hydroxide (KOH).

19. The method of claim 13, wherein the step of removing the layer of an oxide of the metal further comprises plasma etching the layer of an oxide of the metal according to a reactive ion etch process.

20. The method of claim 19, wherein the reactive ion etch process further includes igniting and maintaining a plasma including at least one of fluorocarbons and hydrofluorocarbons.
